(19) United States
(12) Patent Application Publication
(10) Pub. No.: US 2020/0273842 A1
(43) Pub. Date: Aug. 27, 2020

(54) OPTOELECTRONIC MODULE AND DISPLAY ELEMENT

(71) Applicant: OSRAM OLED GmbH, Regensburg (DE)

(72) Inventors: Peter BRICK, Regensburg (DE); Hubert HALBRITTER, Dietfurt (DE); Mikko PERAELAE, Tampere (FI); Joachim REILL, Lappersdorf (DE); Frank SINGER, Regenstauf (DE)

(21) Appl. No.: 16/753,638

(22) PCT Filed: Sep. 21, 2018
(86) PCT No.: PCT/EP2018/075656

§ 371 Date: Apr. 3, 2020

(30) Foreign Application Priority Data
Oct. 9, 2017 (DE) 10 2017 123 402.0

(51) Int. Cl. H01L 25/065; H01L 27/15; H01L 33/58; G02B 30/20; H01L 33/62; H01L 23/00

(52) U.S. Cl. CPC H01L 25/0655; H01L 27/156; H01L 33/58; G02B 30/20; H01L 2224/48227; H01L 24/48; H01L 2224/48091; H01L 2224/48106; H01L 33/62

(57) ABSTRACT

An optoelectronic module is provided with:
a carrier with a main plane of extension,
a first emission region with a plurality of emitters of a first type, which are configured to emit light of at least one predeterminable first color location during operation of the optoelectronic module,
a second emission region with a plurality of emitters of a second type, which are configured to emit light of at least one predeterminable second color location during operation of the optoelectronic module, and
a third emission region with a plurality of emitters of a third type, which are configured to emit light of at least one predeterminable third color location during operation of the optoelectronic module, wherein
the emission regions are arranged spaced apart from each other on the carrier. In addition, a display element with a plurality of optoelectronic modules is specified.

An optoelectronic module and a display element are specified.

An object of the invention is to specify an optoelectronic module that can be operated efficiently. Another object be achieved is to specify a display element that can be operated efficiently.

According to at least one embodiment of the optoelectronic module, the optoelectronic module comprises a carrier with a main plane of extension. The carrier can be a three-dimensional body, which for example has the shape of a cuboid or a cylinder. The main plane of extension of the carrier is parallel to one of the cover surfaces of the cuboid or the cylinder.

Furthermore, the carrier may have a semiconductor body. The semiconductor body can be formed with a semiconductor material such as silicon. It is also possible that the carrier has a carrier plate. The carrier plate can be a printed circuit board or a lead frame. The carrier may include the semiconductor body and the carrier plate. The semiconductor body and the carrier plate can then be interconnected and be in direct contact with each other.

According to at least one embodiment of the optoelectronic module, the optoelectronic module comprises a first emission region with a plurality of emitters of a first type, which are configured to emit light of at least one predeterminable first color location during operation of the optoelectronic module. For example, the first emission region may be a surface on which the emitters of the first type are arranged. Furthermore, the first emission region can be a three-dimensional region that includes the emitters of the first type. The first emission region can be defined by the fact that only emitters of the first type are arranged in the first emission region. It is also possible that all first type emitters of the optoelectronic module are located in the first emission region. The first emission region may be simply connected contiguous. In particular, for the plurality of emitters of the first type, there is then at least one first emission region which is simply connected. Thus the first emission region can be, for example, a surface which is simply connected and on which the emitters of the first type are arranged. The first emission region may extend at least partially or completely parallel to the main plane of extension of the carrier.

The emitters of the first type can be arranged at a distance from each other on the carrier. For example, the emitters of the first type can be arranged side by side in lateral directions parallel to the main plane of extension of the carrier. The emitters of the first type can be luminescent diode chips such as light-emitting diode chips or laser diode chips. Each of the emitters of the first type can be a separate semiconductor chip. It is also possible that at least some of the first type emitters, especially all first type emitters, are part of a single semiconductor chip. This means that the emitters of the first type can be monolithically formed with each other. The semiconductor chip can then be a pixelated semiconductor chip comprising a plurality of emitters of the first type, which can be operated independently of each other.

The emitters of the first type can, for example, emit light of a first color during operation. The first color can be one of the colors red, green or blue, for example. For example, the color location or the color of the light emitted by the emitters of the first type in operation can be adjusted by the materials of the emitters of the first type.

The emitters of the first type can be configured to emit light mainly on the side opposite the carrier during operation. The side of the emitters of the first type facing away from the carrier can thus be a radiation exit surface.

According to at least one embodiment of the optoelectronic module, the optoelectronic module comprises a second emission region with a plurality of emitters of a second type, which are configured to emit light of at least one predeterminable second color location during operation of the optoelectronic module. The second emission region can be, for example, a surface on which the emitters of the second type are arranged. The second emission region can also be a three-dimensional region that includes the emitters of the second type. The second emission region can be defined by the fact that only emitters of the second type are arranged in the second emission region. It is also possible that all second type emitters of the optoelectronic module are located in the second emission region. The second emission region may be simply connected. In particular, for the plurality of second type emitters there is at least one second emission region which is simply connected. The second emission region can thus be, for example, a surface which is simply connected and on which the emitters of the second type are arranged. The second emission region may extend at least partially or completely parallel to the main plane of extension of the carrier.

The emitters of the second type can be arranged at a distance from each other on the carrier. For example, the emitters of the second type can be arranged next to each other in lateral directions parallel to the main plane of extension of the carrier. Emitters of the second type can be luminescent diode chips such as light emitting diode chips or laser diode chips. Each of the emitters of the second type can be a separate semiconductor chip. It is also possible that at least some of the second type emitters, especially all second type emitters, are part of a single semiconductor chip. This means that the emitters of the second type can be monolithically formed with each other. The semiconductor chip may then be a pixelated semiconductor chip comprising a plurality of second type emitters that can be operated independently of each other.

The emitters of the second type can, for example, emit light of a second color during operation. The second color can be one of the colors red, green or blue, for example. The color location or color of the light emitted by the second type emitters in operation can be adjusted, for example, by the materials of the second type emitters.

The emitters of the second type can be configured to emit light mainly on the side facing away from the carrier during operation. The side of the emitter of the second type facing away from the carrier can thus be a radiation exit surface.

According to at least one embodiment of the optoelectronic module, the optoelectronic module comprises a third emission region with a plurality of emitters of a third type, which are configured to emit light of at least one predeterminable third color location during operation of the optoelectronic module. For example, the third emission region may be a surface on which the emitters of the third type are arranged. Furthermore, the third emission region can be a three-dimensional region that includes the emitters of the third type. The third emission region can be defined by the fact that only emitters of third type are arranged in the third emission region. It is also possible that all third type emitters of the optoelectronic module are located in the third emission region. The third emission region can be simply connected. In particular, for the plurality of third type emitters there is at least a third emission region which is simply connected. The third emission region can thus be, for example, a surface which is simply connected and on which the emitters of the third type are arranged. The third emission region may extend at least partially or completely parallel to the main plane of extension of the carrier.

The emitters of the third type can be arranged at a distance from each other on the carrier. For example, third type emitters can be arranged side by side in lateral directions parallel to the main plane of extension of the carrier. The emitters of the third type can be luminescent diode chips such as light emitting diode chips or laser diode chips. Each of the third type emitters can be a separate semiconductor chip. It is also possible that at least some of the third type emitters, especially all third type emitters, are part of a single semiconductor chip. This means that the emitters of the third type can be monolithically formed with each other. The semiconductor chip may then be a pixelated semiconductor chip comprising a plurality of third type emitters that can be operated independently of each other.

The emitters of the third type can, for example, emit light of a third color during operation. The third color can be one of the colors red, green or blue, for example. The color locations or the color of the light emitted by the third type emitters in operation can be adjusted, for example, by the materials of the third type emitters.

The emitters of the third type can be configured to emit light mainly on the side facing away from the carrier during operation. The side of the emitter of the third type facing away from the carrier can thus be a radiation exit surface. According to at least one embodiment of the optoelectronic module, the emission regions are arranged on the carrier at a distance from each other. This can mean that the emission regions do not intersect or overlap or do not interfere with each other. For example, the first emission region and the second emission region do not have a common surface. In particular, none of the emission regions has a common surface with any of the other emission regions. This means that for each of the different emitters there is at least one separate emission region, which has no common surface with any of the other emission regions. For the emitters of the first type there is at least one first emission region which has no common surface with any of the other emission regions. For the emitters of the second type there is at least one second emission region which has no common surface with any of the other emission regions. For the emitters of the third type there is at least one third emission region, which has no common surface with any of the other emission regions. The emission regions can be arranged in lateral directions next to each other on the carrier.

It is also possible that the optoelectronic module has at least two first emission regions. It is also possible that the optoelectronic module has at least two second emission regions. Furthermore, the optoelectronic module may have at least two third emission regions. The emission regions may be spaced apart on the carrier.

In particular, each emission region is configured to emit light of a predeterminable color location independent of other emission regions. The respective emitters emit light of a predeterminable color location. Each of the emitters may have an active area or part of an active area configured to emit light during operation of the optoelectronic module. The emitters can be configured to emit unconverted light during operation. In this case, the wavelength of the light emitted from the active area during operation of an emitter is not changed by, for example, a conversion element.

It is also possible that at least one type of emitter has a conversion element that changes the wavelength of the light emitted from the active area during operation. The emitters of different types can have different conversion elements. For example, the emitters of the first type, the emitters of the second type and the emitters of the third type may each have an active area which, in operation, emits light of the same wavelength or with the same color location. For example, the active area may emit blue light during operation. In this case at least two emitters of different types have different conversion elements.

The emitters of the first type, the emitters of the second type and the emitters of the third type may each have an edge length in the lateral direction of at least 1 μm and at most 300 μm. Preferably, the edge length of the emitters of the first type, the emitters of the second type and the emitters of the third type in lateral direction are each at least 1 μm and at most 10 μm.

The first emission region, the second emission region and the third emission region may each have an edge length in the lateral direction of at least 10 μm and at most 1 mm. The optoelectronic module may have an edge length of at least 30 μm and at most 10 mm in the lateral direction. Furthermore, the optoelectronic module can be surface mounted.

According to at least one embodiment of the optoelectronic module, the optoelectronic module comprises a carrier with a main plane of extension, a first emission region with a plurality of emitters of a first type, which are configured to emit light of at least one predeterminable first color location during operation of the optoelectronic module, a second emission region with a plurality of emitters of a second type, which are configured to emit light of at least one predeterminable second color location during operation of the optoelectronic module, and a third emission region with a plurality of emitters of a third type which are configured to emit light of at least one predeterminable third color location during operation of the optoelectronic module, the emission regions being arranged at a distance from one another on the carrier.

The optoelectronic module described here is based, among others, on the idea that the optoelectronic module can be used in an autostereoscopic display element. This means that the optoelectronic module can be used in a display element that can create a three-dimensional image impression without the need for any other aid, such as glasses. A three-dimensional impression of an image can be created, for example, by directing the light from at least two optoelectronic modules of a display element in different directions. Since the optoelectronic module described herein has a plurality of emitters of the first type, second type and third type, it is already possible for only one optoelectronic module to direct light emitted by, for example, at least two emitters of the first type in different directions during operation.

Advantageously, the emitters of the first type, the emitters of the second type and the emitters of the third type are arranged on only one carrier. Thus the emitters of the first type, the emitters of the second type and the emitters of the third type can be controlled via the carrier. By controlling a plurality of emitters of the same type together, the controlling can be simplified. For example, fewer electrical connections are required overall to control the emitters. In addition, each of the emitters can be made particularly small, as less space is required for the electronics to control the emitters. A small size of the emitters is advantageous for a high resolution, for example of an image displayed by a display element. Furthermore, the three-dimensional impression of an image displayed by the display element can be improved by the emitters having a small size.

According to at least one embodiment of the optoelectronic module, the optoelectronic module comprises exactly one first emission region, exactly one second emission region and exactly one third emission region.

According to at least one embodiment of the optoelectronic module, the emitters of the first type in the first emission region are arranged in the same way as the emitters of the second type in the second emission region and the emitters of the third type in the third emission region. The emitters of the first type can be arranged in the first emission region according to a predeterminable arrangement. The arrangement can be a pattern, for example. The emitters of the first type can be arranged in the emission region along a line or, for example, in a two-dimensional arrangement. The emitters of the first type can be arranged side by side on the carrier. The emitters of the first type can be arranged in a plane parallel to the main plane of extension of the carrier. The emitters of the second type can be arranged in the same predeterminable arrangement as the emitters of the first type. This can mean, for example, that a first emitter of a first type is arranged relative to a second emitter of a first type. Furthermore, in this case a first emitter of a second type is arranged relative to a second emitter of a second type in the same way as the first emitter of the first type is arranged relative to the second emitter of the first type. Furthermore, in this case a first emitter of a third type is arranged relative to a second emitter of a third type in the same way as the first emitter of the first type is arranged relative to the second emitter of the first type. If the arrangement of the emitters of the first type shows a pattern, the arrangement of the emitters of the second type and the arrangement of the emitters of the third type show the same pattern. The same arrangement of the emitters in the respective emission region enables an autostereoscopic display of an image when the optoelectronic module is used in a display element.

According to at least one embodiment of the optoelectronic module, the first emission region has at least ten emitters of the first type, the second emission region has at least ten emitters of the second type and the third emission region has at least ten emitters of the third type. In particular, the first emission region may have at least 30 emitters of the first type, the second emission region may have at least 30 emitters of the second type and the third emission region may have at least 30 emitters of the third type. Preferably the first emission region has as many emitters as the second emission region and as the third emission region. This means that a plurality of emitters of the same type can be controlled together and fewer electrical connections are required to control the emitters. In addition, a large number of emitters enables an autostereoscopic display of an image when the optoelectronic module is used in a display element.

According to at least one embodiment of the optoelectronic module, an optical element is arranged downstream of each of the emission regions in a direction of emission. The direction of emission can be the direction in which most of the light emitted by the emitters in operation is emitted. For example, the direction of radiation may be perpendicular to the main plane of extension of the carrier. Thus the optical element can be arranged in a vertical direction above the respective emission region, the vertical direction being perpendicular to the main plane of extension of the carrier. The optical element can completely cover the respective emission region. This means that most of the light emitted by each of the emitters passes through the optical element before leaving the optoelectronic module.

Each of the optical elements may have the same design and may be arranged in the same way downstream of the respective emission region in the direction of emission. The optical element may be at least partially transparent to the light emitted by the emitters. For example, the optical element is a lens. In particular, the optical element may be formed with a cylindrical lens. Advantageously, the optical elements enable a three-dimensional image impression. This means that optoelectronic modules can create a three-dimensional image impression in a display element with optical elements arranged in this way.

According to at least one embodiment of the optoelectronic module, at least one optical element is arranged downstream of the optoelectronic module in one direction of radiation. This means that an optical element can be arranged vertically over the entire optoelectronic module. The optical element can cover all emitters of the optoelectronic module. The optical element can be a lens, for example a cylindrical lens. Advantageously, the optical element enables a three-dimensional image impression. In this case, only an optical element is required to create a three-dimensional image impression. This means that optoelectronic modules in a display element with an optical element arranged in this way can create a three-dimensional image impression.

According to at least one embodiment of the optoelectronic module, each of the emission regions has a first emitter and a second emitter, wherein the light emitted by the first emitters in operation is directed by the optical element in a different direction than the light emitted by the second emitters in operation. The optical element can be configured to direct light, which hits the optical element in different areas, in different directions. This means that the light emitted by the emitters in operation has a main direction of radiation after passing the optical element, which may be different from the vertical direction.

Thus the light from a first emitter of the first type can have a first main direction of emission after passing the optical element. The light emitted by a second emitter of a first type may have a second main emission direction after passing through the optical element. Preferably, the light emitted by a first emitter of a second type in operation has the same main emission direction after passing the optical element as the light emitted by the first emitter of the first type after passing through the optical element. In addition, the light emitted by a first emitter of a third type during operation preferably has the same main emission direction after passing through the optical element as the light emitted by the first emitter of the first type after passing through the optical element. This means that the emitters of the first type in the first emission region can be arranged in the same way as the emitters of the second type in the second emission region and the emitters of the third type in the third emission region.

Furthermore, the light emitted by a second emitter of a second type during operation preferably has the same main radiation direction after passing through the optical element as the light emitted by the second emitter of the first type after passing through the optical element. The light emitted by a second emitter of a third type in operation may have the same main direction of emission after passing through the optical element as the light emitted by the second emitter of the first type after passing through the optical element.

By directing the light emitted by the emitters in different main radiation directions, a three-dimensional image impression can be created when a plurality of optoelectronic modules are arranged in a display element. Each of the modules represents one pixel of a two-dimensional image. To create a three-dimensional impression of the two-dimensional image for an observer, different perspectives of the two-dimensional image can be displayed in different spatial directions. In this context, a perspective describes a two-dimensional representation of an image. For example, the first perspective is perceived by an observer as a two-dimensional representation of an image within the field of view.

By directing the light emitted by the emitters into different main radiation directions, different perspectives of each pixel are thus represented. The light emitted and deflected by the first emitters can represent a first perspective of a pixel. The light emitted and deflected by the second emitters can represent a second perspective of the same pixel. The light emitted by two different optoelectronic modules can represent two different pixels of the image to be displayed.

The different main radiation directions can be arranged on a straight line. In this case a three-dimensional image impression can be created along a line. If the main radiation directions are arranged in one plane, a three-dimensional image impression can be created within one plane.

The optoelectronic module described herein can thus be used in a display element with which a three-dimensional impression of a two-dimensional image impression can be created for an observer. The display element can be an autostereoscopic display, for example.

According to at least one embodiment of the optoelectronic module, the first emitters and the second emitters are each located on a common connecting axis. This means that the first emitter of the first type, the first emitter of the second type and the first emitter of the third type lie on a common connecting axis. Furthermore, the second emitter of the first type, the second emitter of the second type and the second emitter of the third type lie on a further common connecting axis. For example, the connecting axis can be a straight line connecting the first emitters. Since the first emitters and the second emitters are each located on a common connecting axis, the emitters in the first emission region can be arranged in the same way as in the second and third emission regions. Such an arrangement of the emitters enables the creation of a three-dimensional image impression when the optoelectronic module is arranged in a display element.

According to at least one embodiment of the optoelectronic module, the optoelectronic module has a control unit for separate control of the emission regions. The control unit can be located in the carrier. It is also possible that the control unit is arranged on the carrier, for example in lateral directions next to the emitters. The control unit is configured to control each of the emission regions separately. Thus, for example, the intensity of the light emitted by the different emitters can be adjusted. The emitters can be controlled by pulse width modulation, for example. Advantageously, only one control unit is required for a plurality of different emitters.

According to at least one embodiment of the optoelectronic module, the emitters of each emission region are monolithically formed with each other. This means that the emitters of the first type are monolithically formed with each other, the emitters of the second type are monolithically formed with each other and the emitters of the third type are monolithically formed with each other. For this purpose the emitters can be arranged on a common semiconductor body. For example, the emitters of each emission region can be manufactured together. This means that fewer electrical connections are required to control the emitters.

According to at least one embodiment of the optoelectronic module, the emitters of each emission region are arranged separately on the carrier. This means that each of the emitters can be a single semiconductor chip. The individual semiconductor chips can be arranged on the carrier. The carrier may include a carrier plate. The emitters can be arranged on the carrier plate. Thus the emitters of an emission region are not monolithically formed with each other. The emitters can therefore be manufactured separately. This enables, for example, the sorting out of faulty emitters before they are applied to the carrier.

According to at least one embodiment of the optoelectronic module, the emitters of each emission region are arranged along an at least 1-dimensional lattice. This means, for example, that the emitters of the first type are arranged along a lattice that is at least one-dimensional. Preferably the emitters of the second type are arranged along the same at least one-dimensional lattice as the emitters of the first type. In addition, emitters of third type can also be arranged along the same lattice. The lattice can extend parallel to the main plane of extension of the carrier. Arranging the emitters along a lattice allows the light emitted by the emitters to be deflected in different directions by an optical element to create a three-dimensional image impression of a pixel or a two-dimensional image.

According to at least one embodiment of the optoelectronic module, the emitters of each emission region are arranged at the nodes of a 2-dimensional lattice. This means, for example, that emitters of the first type are located at the nodes of a two-dimensional lattice. Preferably, the emitters of the second type are located at the nodes of the same lattice in the second emission region, which is located at a distance from the first emission region. Furthermore, emitters of the third type can also be located at the nodes of the same lattice in the third emission region. For example, the two-dimensional lattice can be a regular rectangular or hexagonal lattice. The lattice may extend parallel to the main plane of extension of the carrier. By arranging the emitters at the nodes of a two-dimensional lattice, it is possible to create a three-dimensional image impression of a pixel or a two-dimensional image.

According to at least one embodiment of the optoelectronic module, the substrate has at least one of the following structures:

integrated circuit,

complementary metal-oxide-semiconductor structure,

application-specific integrated circuit.

The structure can be configured to control the emitters during operation of the optoelectronic module. For this purpose, the structure can be located in the carrier or on the carrier at a distance from the emitters.

A display element is also specified. The display element can be part of a smartphone, a television or a video wall, for example. The display element can have a display, which can be placed on a wall, a column or a box, for example. In particular, the display element is an autostereoscopic display element. With the autostereoscopic display element, for example, an image can be displayed three-dimensionally for an observer, whereby the three-dimensional representation can be perceived by the naked eye, i.e. without an aid such as polarized glasses or shutter glasses.

According to at least one embodiment of the display element, the display element has a plurality of optoelectronic modules, the optoelectronic modules being arranged side by side in the lateral direction at the nodes of a regular two-dimensional lattice on a display element carrier, wherein the lateral direction is parallel to the main plane of extension of the display element carrier, and each of the emission regions comprises a first emitter and a second emitter, wherein the light emitted by the first emitters in operation exits the display element at a different exit angle than the light emitted by the second emitters in operation.

The display element carrier may have a main plane of extension which is parallel to the main plane of extension of the carrier of the optoelectronic module. The optoelectronic modules are arranged on the display element carrier in such a way that the radiation exit surface of the emitters faces away from the display element carrier. For example, the regular two-dimensional lattice can be a rectangular lattice or a hexagonal lattice. The optoelectronic modules can be arranged at a distance from each other. It is also possible that the optoelectronic modules are arranged directly next to each other. Since the optoelectronic modules can be surface mounted, they can be electrically connected to electrical contacts of the display element carrier on a side of the display element carrier facing the optoelectronic modules. Thus the optoelectronic modules can be controlled via the display element carrier.

The exit angle from the display element can be measured in relation to the vertical direction. This means that not all of the light emitted by the emitters during operation exits the display element in a vertical direction. For example, the light emitted by the first emitters of each of the emission regions during operation may exit the display element at a first exit angle. Furthermore, the light emitted by the second emitters of each of the emission regions during operation can exit the display element at a second exit angle. In total, light emitted from different emitters during operation can exit the display element at a plurality of exit angles.

Because the light emitted by the first emitters during operation exits the display element at the same exit angle, a first perspective of an image to be displayed can be imaged by the first emitters at the first exit angle. In addition, a second perspective of the image to be displayed can be displayed by the second emitters at the second exit angle. Thus, the image to be displayed can be shown from a plurality of exit angles. This means that different perspectives of the image to be displayed are shown at different angles. Thus, a three-dimensional image impression to be displayed can be perceived by an observer without the need for additional aids, such as polarized or shutter glasses.

According to at least one embodiment of the display element, at least one optical element is arranged downstream of the optoelectronic modules in one direction of radiation. The optical element can cover all optoelectronic modules of the display element. The optical element may be a lens, such as a cylindrical lens, for example. In this case only one optical element is required for the entire display element. Separate optical elements for each of the emission regions are not required in this case. The shape of the lens can deviate from the shape of a cylindrical lens within a tolerance range. The tolerance range can be given by the manufacturing process of the lens, for example. It is also possible that the optical element is a plurality of lenses, for example a lens array, with the lenses arranged side-by-side in the lateral direction. The optical element may be configured to direct the light emitted by the first emitters in a different direction than the light emitted by the second emitters during operation. Thus a three-dimensional image impression can be created for an observer.

According to at least one embodiment of the display element, different perspectives of an image can be displayed during operation, whereby the simultaneous perception of different perspectives creates a three-dimensional image impression. The different perspectives of an image to be displayed can be represented by displaying the image to be displayed at different angles in relation to the display element. For example, the light emitted by the first emitters during operation can be directed in a different direction than the light emitted by the second emitters during operation. If at least two different perspectives are perceived simultaneously by an observer, each of the two eyes of the observer can perceive a different perspective, which creates a three-dimensional image impression.

In the following, the optoelectronic module and the display element described herein are explained in more detail in conjunction with exemplary embodiments and the associated figures.

FIGS. 1, 2 and 3 show schematic cross-sections through an optoelectronic module according to various exemplary embodiments.

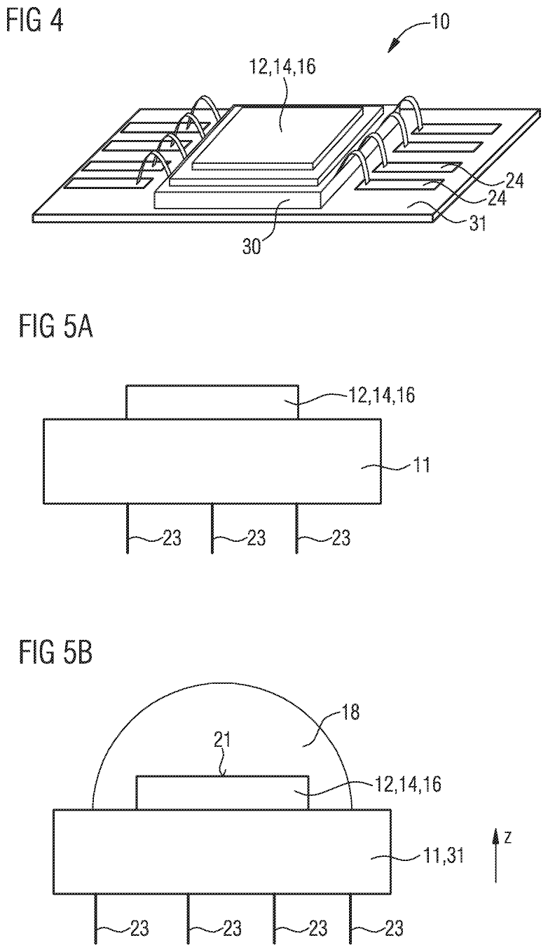

FIG. 4 shows an optoelectronic module according to an exemplary embodiment.

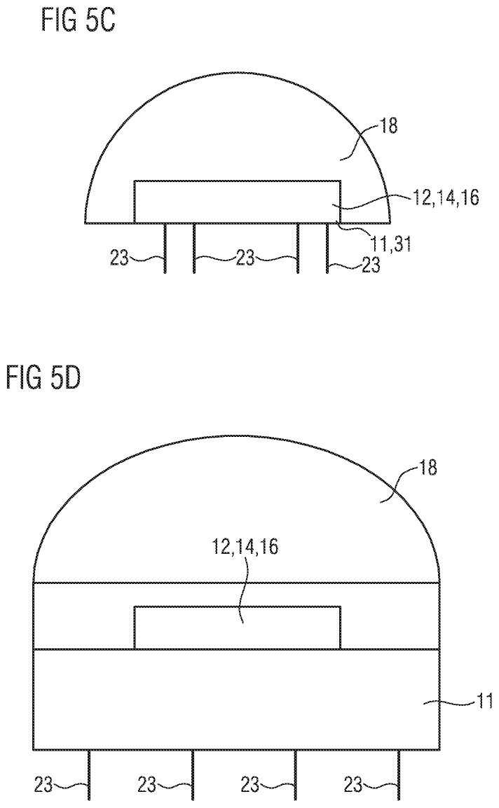

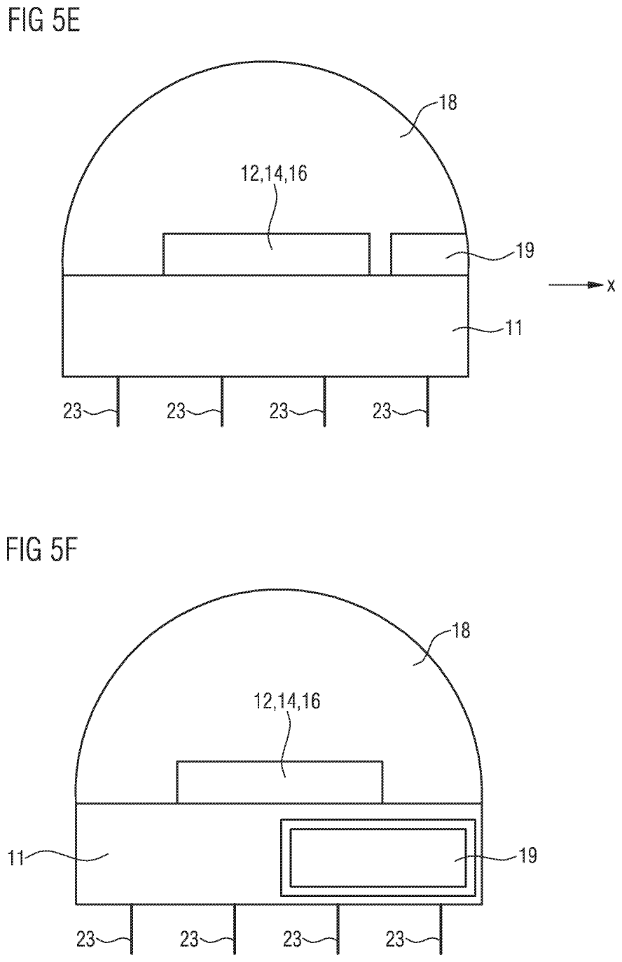

FIGS. 5A, 5B, 5C, 5D, 5E and 5F show schematic cross-sections through an emission region according to various exemplary embodiments.

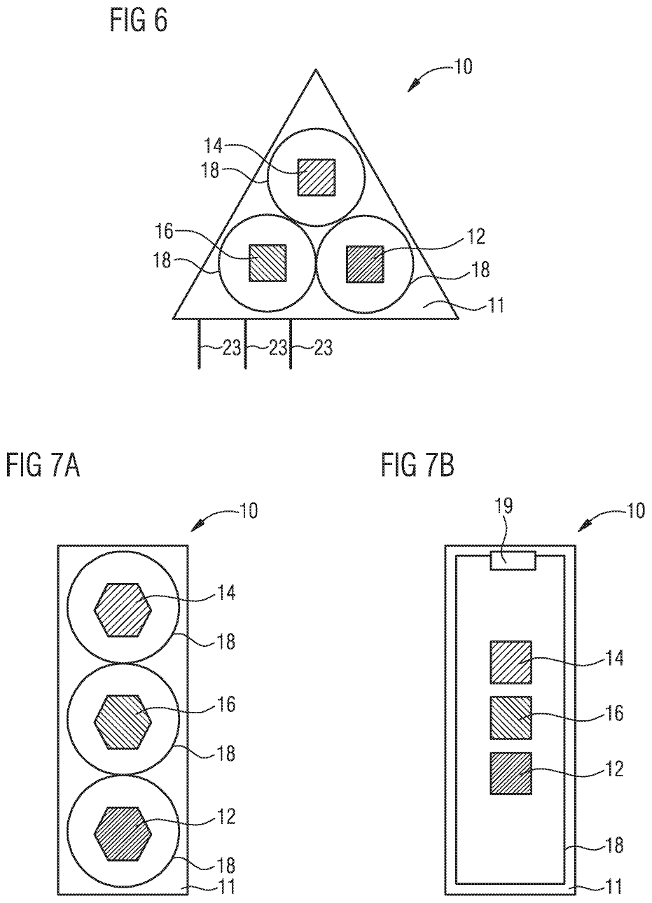

FIGS. 6, 7A, 7B, 7C, 7D, 7E, 7F, 8A and 8B show plan views of an optoelectronic module according to various exemplary embodiments.

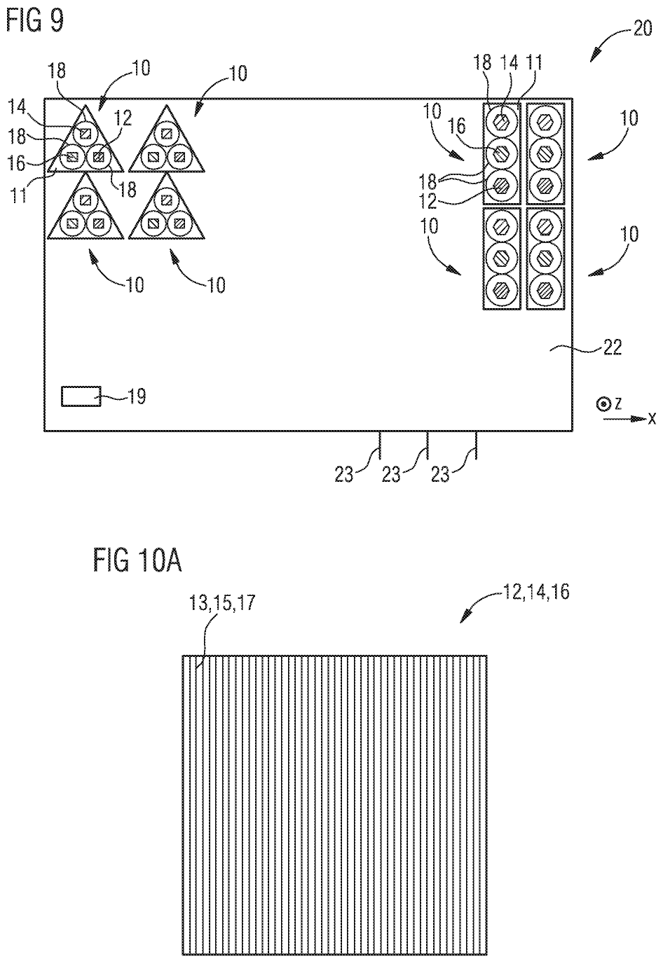

FIG. 9 shows a display element according to an exemplary embodiment.

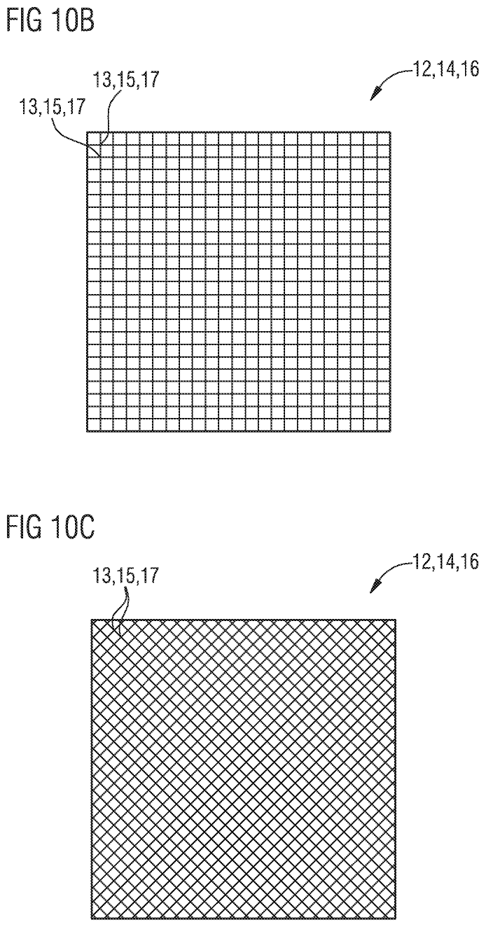

FIGS. 10A, 10B and 10C show schematic plan views of exemplary embodiments of an emission region.

Identical, similar or similarly acting elements are provided in the figures with the same reference signs. The figures and the proportions of the elements depicted in the figures with respect to each other are not to be regarded as true to scale. Rather, individual elements may be depicted as oversized for better presentation and/or comprehensibility.

FIG. 1 shows a schematic cross-section of an optoelectronic module 10 according to an exemplary embodiment. The optoelectronic module 10 is surface mountable and can be arranged on a display element carrier. The optoelectronic module 10 has a carrier 11 with a main plane of extension. The carrier 11 has a carrier plate 31. The carrier plate 31 can be a printed circuit board or a lead frame, for example. In addition, carrier 11 has a semiconductor body 30. The semiconductor body 30 can be formed with a semiconductor material. The semiconductor body 30 is arranged on the carrier plate 31 and connected to it. The semiconductor body 30 is electrically connected to electrical contacts 24 of the carrier plate 31.

Furthermore, the optoelectronic module 10 has a first emission region 12 with a plurality of emitters of the first type 13, which are configured to emit light of at least one predeterminable first color location during operation of the optoelectronic module 10. In this exemplary embodiment, the first emission region 12 has four emitters of the first type 13. The emitters of the first type 13 are arranged side by side in lateral direction x, the lateral direction x being parallel to the main plane of extension of carrier 11.

The first emission region 12 is defined by the fact that in the first emission region 12 only emitters of the first type 13 are arranged. The first emission region 12 can be a surface on which all emitters of the first type 13 are arranged or a three-dimensional region which includes all emitters of the first type 13. The first emission region 12 is formed simply connected.

The optoelectronic module 10 also has a second emission region 14 with a plurality of second type 15 emitters. The emitters of the second type 15 are configured to emit light of at least one predeterminable second color location during operation of the optoelectronic module 10. In this exemplary embodiment, the second emission region 14 has four emitters of second type 15. The emitters of the second type 15 are arranged x next to each other in lateral direction.

The second emission region 14 is defined by the fact that in the second emission region 14 only emitters of second type 15 are arranged. The second emission region 14 can be a surface on which all emitters of second type 15 are arranged or a three-dimensional region which includes all emitters of second type 15. The second emission region 14 is formed simply connected.

The optoelectronic module 10 also has a third emission region 16 with a plurality of third type 17 emitters. The emitters of the third type 17 are configured to emit light of at least one predeterminable third color location during operation of the optoelectronic module 10. In this exemplary embodiment, the third emission region 16 has four emitters of the third type 17. The emitters of the third type 17 are arranged next to each other in lateral direction x.

The third emission region 16 is defined by the fact that in the third emission region 16 only emitters of third type 17 are arranged. The third emission region 16 can be a surface on which all emitters of third type 17 are arranged or a three-dimensional region which includes all emitters of third type 17. The third emission region 16 is formed simply connected.

The three emission regions 12, 14, 16 are arranged at a distance from each other on the semiconductor body 30. The three emission regions 12, 14, 16 can be connected to the semiconductor body 30 by direct wafer bonding. The emitters 13, 15, 17 have a radiation exit surface 21, which faces away from the carrier 11.

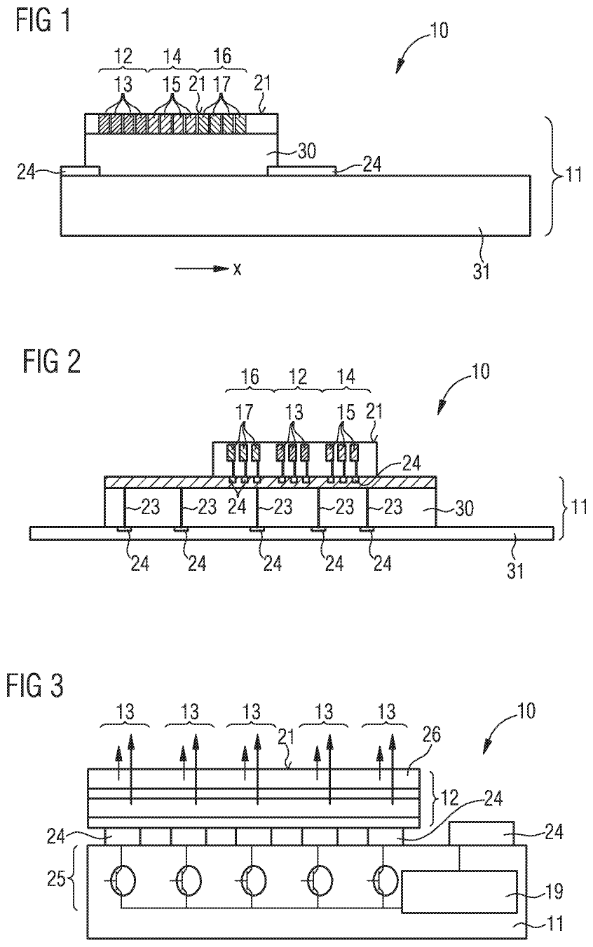

FIG. 2 shows a schematic cross-section of an optoelectronic module 10 according to another exemplary embodiment. The carrier 11 has a carrier plate 31, which in this case is a printed circuit board. In addition, carrier 11 has a semiconductor body 30. The emission regions 12, 14, 16 are arranged on the semiconductor body 30. For each of the emission regions 12, 14, 16 an electrical connection 23 is arranged in the semiconductor body 30. The electrical connections 23 extend from a side of the semiconductor body 30 facing the emission regions 12, 14, 16 to the carrier plate 31. The electrical connections 23 are electrically connected to electrical contacts 24 of the carrier plate 31. The semiconductor body 30 also has two additional electrical connections 23, via which, for example, additional information can be passed on to the optoelectronic module 10. Each of the emission regions 12, 14, 16 has three emitters 13, 15, 17. Advantageously, only one electrical connection 23 in semiconductor body 30 is required for each of the emission regions 12, 14, 16. Thus, the semiconductor body 30 has electrical contacts 24 on a side facing the emission regions 12, 14, 16. The number of electrical contacts 24 of the semiconductor body 30 is at least equal to the number of emitters 13, 15, 17 plus 1. Each of the emitters 13, 15, 17 is connected to one of the electrical terminals 23.

FIG. 3 shows a schematic cross-section of an optoelectronic module 10 according to another exemplary embodiment. The carrier 11 has an integrated circuit 25 such as a complementary metal-oxide-semiconductor structure or an application-specific integrated circuit for controlling the emitters 13, 15, 17. The integrated circuit 25 is electrically connected to a control unit 19. The control unit 19 can be electrically contacted via an electrical contact 24 on a side of carrier 11 facing emission regions 12, 14, 16. Exemplarily, FIG. 3 shows a first emission region 12 with five emitters of first type 13. The emitters of the first type 13 are monolithically formed with each other and can be controlled separately by the integrated circuit 25. For this purpose electrical contacts 24 are arranged between the emitters of the first type 13 and the carrier 11. At the radiation exit surface 21 of the emitters of the first type 13 a conversion element 26 is arranged for the conversion of the wavelength of the light emitted by the emitters of the first type 13.

FIG. 4 shows an optoelectronic module 10 according to an exemplary embodiment. The semiconductor body 30 with the emission regions 12, 14, 16 is arranged on the carrier plate 31. The semiconductor body 30 is electrically connected to the electrical contacts 24 of the carrier plate 31. The electrical contacts 24 are arranged on a side of the carrier plate 31 facing the semiconductor body 30 in lateral direction x next to the semiconductor body 30. The emission regions 12, 14, 16 are schematically shown as one surface.

FIG. 5A shows a schematic cross-section of an exemplary embodiment of an emission region 12, 14, 16. The first emission region 12 is shown as an example and arranged on the carrier 11. This and the following may also relate either to the second emission region 14 or the third emission region 16. The emitters of the first type 13 are not shown separately in the first emission region 12. The carrier 11 can be a carrier plate 31. On a side of the carrier 11 facing away from the first emission region 12, this carrier 11 has three electrical connections 23, via which the emitters of the first type 13 can be controlled. The emitters of the first type 13 can be controlled by pulse width modulation, for example. Thus the emitters of the first type 13 can be controlled separately from the emitters of the second type 15 and the emitters of the third type 17.

FIG. 5B shows a schematic cross-section of another exemplary embodiment of a first emission region 12. In comparison to the exemplary embodiment of FIG. 5A, the carrier 11 has four electrical connections 23 for controlling the emitters of the first type 13. The first emission region 12 may be located on a semiconductor body 30. In this case, the first emission region 12 and the semiconductor body 30 are schematically shown as one element. In this case, the semiconductor body 30 with the first emission region 12 is arranged on a carrier plate 31. In addition, an optical element 18 is arranged on the radiation exit surface 21 of the emitter of the first type 13. The optical element 18 is arranged in a vertical direction z, which is perpendicular to the main plane of extension of the carrier 11, above the first emission region 12. The optical element 18 can be a lens, for example. A lens can increase the extraction efficiency of the light emitted in operation from the first type emitters 13 from the optoelectronic module 10.

FIG. 5C shows a schematic cross-section of another exemplary embodiment of the first emission region 12. In comparison to the exemplary embodiment of FIG. 5B, carrier 11 is a carrier plate 31 or a printed circuit board. In this case the optical element 18 is stable enough to hold the emitters of first type 13 on the carrier 11.

FIG. 5D shows a schematic cross-section of another exemplary embodiment of the first emission region 12. In comparison to the exemplary embodiment of FIG. 5B, the optical element 18 is arranged at a distance from the first emission region 12. For example, air may be arranged between the optical element 18 and the first emission region 12. It is also possible that there is a material between the optical element 18 and the first emission region 12 which is at least partially transparent to the light emitted by the emitters of the first type 13 in operation. Thus, the optoelectronic module 10 has another refractive surface between the emitters of first type 13 and the surroundings of the optoelectronic module 10. Therefore the coupling efficiency or other optical properties can be improved.

FIG. 5E shows a schematic cross-section of another exemplary embodiment of the first emission region 12. In comparison to the exemplary embodiment of FIG. 5B, the control unit 19 is arranged in lateral direction x next to the first emission region 12. The control unit 19 is located on the carrier 11. The optical element 18 covers the first emission region 12 and also the control unit 19, which can perform various functions and can be used as a driver or memory, for example.

FIG. 5F shows a schematic cross-section of another exemplary embodiment of the first emission region 12. In comparison to the exemplary embodiment of FIG. 5E, the control unit 19 is located in carrier 11. Thus, no space is required for the control unit 19 on the radiation exit surface 21 of the emitter of the first type 13.

FIG. 6 shows a plan view of an optoelectronic module 10 according to another exemplary embodiment. On carrier 11, the first emission region 12, the second emission region 14 and the third emission region 16 are arranged at a distance from each other. The carrier 11 can be a carrier plate 31. The emitters 13, 15, 17 in emission regions 12, 14, 16 are not shown individually. The emitters 13, 15, 17 of each emission region 12, 14, 16 may be monolithically formed with each other. The emitters 13, 15, 17 of each emission region 12, 14, 16 can be located at the nodes of a one-dimensional lattice or at the nodes of a two-dimensional lattice. At the radiation exit surface 21 of the emitters 13, 15, 17 an optical element 18 is arranged above each of the emission regions 12, 14, 16. Thus, an optical element 18 is arranged downstream of each of the emission regions 12, 14, 16 in an emission direction. In the plan view, carrier 11 of this exemplary embodiment has the shape of a triangle. In addition, the carrier 11 has three electrical connections 23 to control the three emission regions 12, 14, 16.

The optical elements 18 are preferably of the same design and are arranged directly above emission regions 12, 14, 16. Thus, light emitted by first emitters 27 of each type can be directed in the same direction for each of the emission regions 12, 14, 16, which is different from the direction in which the light emitted by second emitters 28 of each type is directed.

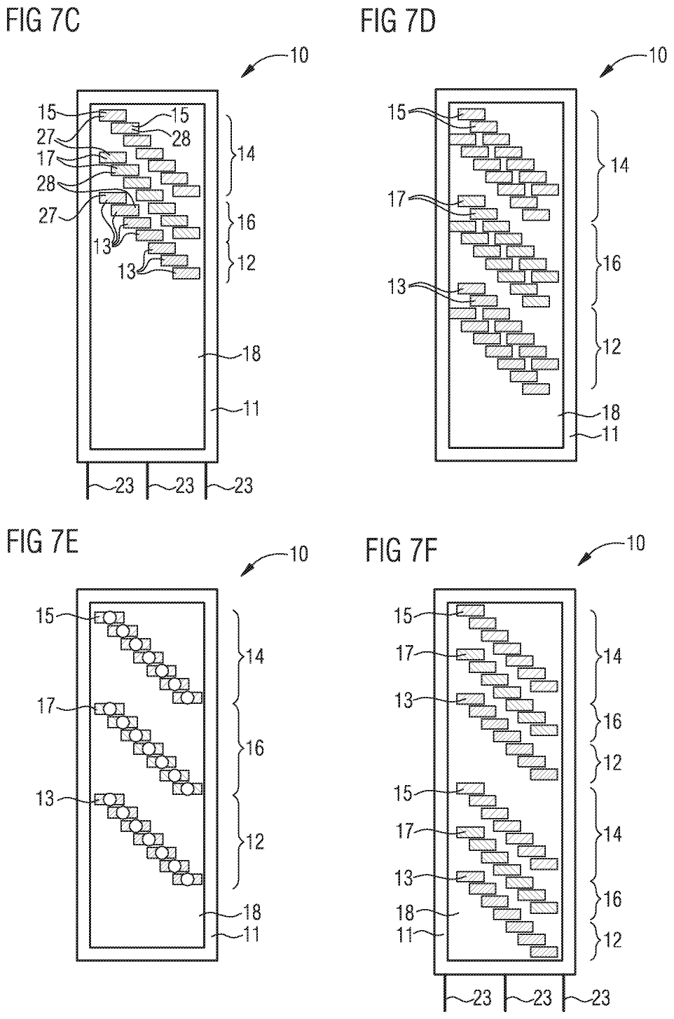

FIG. 7A shows a plan view of an optoelectronic module 10 according to another exemplary embodiment. In comparison to the exemplary embodiment of FIG. 6, the three emission regions 12, 14, 16 with their respective optical elements 18 are arranged along a connecting axis. Accordingly, carrier 11 has the shape of a rectangle in plan view.

FIG. 7B shows a plan view of an optoelectronic module 10 according to another exemplary embodiment. Compared to the exemplary embodiment of FIG. 7A, only one optical element 18 is arranged downstream of the optoelectronic module 10 in the direction of radiation. The optical element 18 completely covers the three emission regions 12, 14, 16. The optical element 18 can be a cylindrical lens, for example. By placing the emitters of the first type 13 in the first emission region 12 in the same way as the emitters of the second type 15 in the second emission region 14 and the emitters of the third type 17 in the third emission region 16, when the optoelectronic module 10 is in operation the cylindrical lens directs the light emitted by the first emitters 27 in a different direction from the light emitted by the second emitters 28. Furthermore, the control unit 19 is arranged on the carrier 11 in lateral direction x next to the emission regions 12, 14, 16.

FIG. 7C shows a plan view of an optoelectronic module 10 according to another exemplary embodiment. In comparison to the exemplary embodiment of FIG. 7B, the first emission region 12 has seven separate emitters of the first type 13. The emitters of the first type 13 are arranged separately from each other on carrier 11. The emitters of the first type 13 are therefore not monolithically formed with each other. In addition, the second emission region 14 has seven emitters of the second type 15 and the third emission region 16 has seven emitters of the third type 17. The emitters of the second type 15 and the emitters of the third type 17 are also arranged separately on carrier 11. The emitters of the first type 13 in the first emission region 12 are arranged in the same way as the emitters of the second type 15 in the second emission region 14 and the emitters of the third type 17 in the third emission region 16. The emitters 13, 15, 17 of each emission region 12, 14, 16 are arranged along a one-dimensional lattice. Furthermore, first emitters 27 of each emission region 12, 14, 16 are arranged along a common connecting axis. Furthermore, second emitters 28 of each emission region 12, 14, 16 are arranged along another common connecting axis. Thus the light emitted by the first emitters 27 in operation is deflected by the optical element 18 in a different direction than the light emitted by the second emitters 28 in operation.

The emitters 13, 15, 17 can have an edge length in lateral direction x of <50 μm. The control unit 19 is located in carrier 11. In addition, the carrier 11 has three electrical connections 23, via which the three emission regions 12, 14, 16 can be controlled.

FIG. 7D shows a plan view of an optoelectronic module 10 according to another exemplary embodiment. Compared to the exemplary embodiment of FIG. 7C, each of the emission regions 12, 14, 16 has fourteen emitters 13, 15, 17. The emitters 13, 15, 17 of each emission region 12, 14, 16 are arranged at the nodes of a two-dimensional lattice.

FIG. 7E shows a plan view of an optoelectronic module 10 according to another exemplary embodiment. The structure corresponds to the exemplary embodiment of FIG. 7C. It is shown here that the range from which each of the emitters 13, 15, 17 can emit light during operation is smaller than the lateral extent of each of the emitters 13, 15, 17. The range from which each of the emitters 13, 15, 17 can emit light during operation is shown here with a circle in the middle of each of the emitters 13, 15, 17.

FIG. 7F shows a plan view of an optoelectronic module 10 according to another exemplary embodiment. Compared to the exemplary embodiment of FIG. 7C, the optoelectronic module 10 has two first emission regions 12, two second emission regions 14 and two third emission regions 16. The emission regions 12, 14, 16 are arranged at a distance from each other on carrier 11. In the lateral direction x, a second emission region 14 and a third emission region 16 are arranged between a first emission region 12 and another first emission region 12. Each of the emission regions 12, 14, 16 is simply connected.

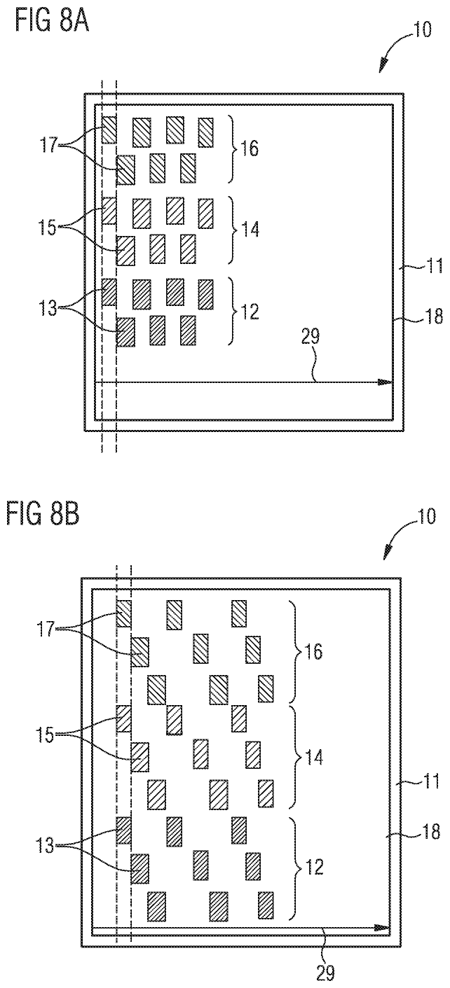

FIG. 8A shows a plan view of an optoelectronic module 10 according to another exemplary embodiment. Each of the three emission regions 12, 14, 16 has seven emitters 13, 15, 17. The emitters 13, 15, 17 are arranged along two straight lines in each emission region 12, 14, 16. Furthermore, the first emitters 27 are arranged along a common connecting axis. An optical element 18 is arranged downstream of emitters 13, 15, 17 in the direction of radiation, covering all emitters 13, 15, 17. Since the emitters 13, 15, 17 are covered by a common optical element 18, the light emitted by the emitters 13, 15, 17 during operation can be directed by the optical element 18 in different directions along a straight line. The emitters 13, 15, 17 are thus aligned along an axis 29 of the optical element 18 so that, for example, each emitter of the first type 13 is located at a different position along the axis 29 of the optical element 18. The emitters of the second type 15 and the emitters of the third type 17 are also arranged at different positions along the axis 29 of the optical element 18. An optoelectronic module 10 according to this exemplary embodiment can be used in a display element 20, in which a three-dimensional image impression is created for an observer along one direction.

FIG. 8B shows a plan view of an optoelectronic module 10 according to another exemplary embodiment. In comparison to the exemplary embodiment of FIG. 8A, each emission region 12, 14, 16 has nine emitters 13, 15, 17, which are arranged along three different straight lines. The emitters 13, 15, 17 of each type are aligned along the axis 29 of the optical element 18, so that the emitters 13, 15, 17 of a type are each located at different positions along the axis 29 of the optical element 18. An optoelectronic module 10 according to this exemplary embodiment can also be used in a display element 20, in which a three-dimensional image impression is created for an observer along one direction.

FIG. 9 shows a plan view of an exemplary embodiment of a display element 20. The display element 20 has a plurality of optoelectronic modules 10. The optoelectronic modules 10 are arranged in lateral direction x next to each other at the nodes of a regular two-dimensional lattice on a display element carrier 22. In addition, each of the emission regions 12, 14, 16 has a first emitter 27 and a second emitter 28, the light emitted by the first emitters 27 during operation exiting the display element 20 at a different exit angle than the light emitted by the second emitters 28 during operation. The exit angle can be measured in relation to the vertical direction z. Furthermore, the display element 20 has a control unit 19 and electrical connections 23 for controlling the different emission regions 12, 14, 16.

FIG. 9 shows an example of the arrangement of four optoelectronic modules 10 according to the exemplary embodiment shown in FIG. 6 at the nodes of a two-dimensional lattice on the display element carrier 22. As a further example, the arrangement of four optoelectronic modules 10 according to the exemplary embodiment shown in FIG. 7A at the nodes of a two-dimensional lattice on the display element carrier 22 is also shown. Preferably, however, a display element 20 has optoelectronic modules 10 of the same exemplary embodiment. Furthermore, a large part or the entire surface of the display element carrier 22 may be covered with optoelectronic modules 10 and not only a small part as shown in FIG. 9.

In particular, the display element 20 is an autostereoscopic display element. With the autostereoscopic display element 20, for example, an image can be displayed three-dimensionally for an observer, whereby the three-dimensional display can be perceived by the observer with the naked eye, i.e. without an aid such as polarized or shutter glasses.

The optical elements 18 are arranged in such a way that the light emitted by the first emitters 27 during operation exits the display element 20 at a first exit angle and that the light emitted by the second emitters 28 during operation exits the display element 20 at a second exit angle different from the first. Thus, different perspectives of an image to be displayed can be shown at different angles by the display element 20. Therefore, the simultaneous perception of different perspectives can create a three-dimensional image impression for an observer.

FIG. 10A shows a schematic plan view of an emission region 12, 14, 16. The emission region can be the first emission region 12, the second emission region 14 or the third emission region 16. It is shown schematically that the emitters 13, 15, 17 in the emission region 12, 14, 16 are arranged along a one-dimensional lattice. If an optoelectronic module 10 with such an emission region 12, 14, 16 is used in a display element 20, a three-dimensional image impression can be created for an observer in one dimension or along one direction.

FIG. 10B shows a schematic plan view of another emission region 12, 14, 16. It is shown schematically that the emitters 13, 15, 17 in the emission region 12, 14, 16 are arranged along a two-dimensional lattice. If an optoelectronic module 10 with such an emission region 12, 14, 16 is used in a display element 20, a three-dimensional image impression can be created for an observer in two dimensions.

FIG. 10C shows a schematic plan view of a further emission region 12, 14, 16. It is shown schematically that the emitters 13, 15, 17 in the emission region 12, 14, 16 are arranged along a two-dimensional lattice. Compared to the exemplary embodiment of FIG. 10B, the lattice is rotated by 45°. If an optoelectronic module 10 with such an emission region 12, 14, 16 is used in a display element 20, a three-dimensional image impression can be created for an observer in two dimensions.

The invention is not limited by the description of the exemplary embodiments. Rather, the invention includes any new feature and any combination of features, which in particular includes any combination of features in the patent claims, even if that feature or combination itself is not explicitly stated in the patent claims or the exemplary embodiments.

The present patent application claims the priority of the German patent application DE 10 2017 123 402.0, the disclosure content of which is hereby incorporated by reference.

### LIST OF REFERENCE SIGNS

10: optoelectronic module

11: carrier

12: first emission region

13: emitter of the first type

14: second emission region

15: emitter of the second type

16: third emission region

17: emitter of the third type

18: optical element

19: control unit

20: display element

21: radiation exit surface

22: display element carrier

23: electrical connection

24: electrical contact

25: integrated circuit

26: conversion element

27: first emitter

28: second emitter

29: axis

30: semiconductor body

31: carrier plate

x: lateral direction

z: vertical direction

1. An optoelectronic module with:
a carrier with a main plane of extension,
a first emission region with a plurality of emitters of a first type, which are configured to emit light of at least one predeterminable first color location during operation of the optoelectronic module,
a second emission region with a plurality of emitters of a second type, which are configured to emit light of at least one predeterminable second color location during operation of the optoelectronic module, and
a third emission region with a plurality of emitters of a third type, which are configured to emit light of at least one predeterminable third color location during operation of the optoelectronic module, wherein
the emission regions are arranged spaced apart from each other on the carrier,
the emitters of each emission region are arranged at the nodes of a 2-dimensional lattice, and
the first emission region is simply connected.

2. The optoelectronic module according to claim 1, wherein the emitters of a first type in the first emission region are arranged in the same way as the emitters of a second type in the second emission region and the emitters of a third type in the third emission region.

3. The optoelectronic module according to claim 1, wherein the first emission region has at least ten emitters of a first type, the second emission region has at least ten emitters of a second type and the third emission region has at least ten emitters of a third type.

4. The optoelectronic module according to claim 1, wherein an optical element is arranged downstream of each of the emission regions in an emission direction.

5. The optoelectronic module according to claim 1, wherein at least one optical element is arranged downstream of the optoelectronic module in an emission direction.

6. The optoelectronic module according to claim 4, wherein each of the emission regions has a first emitter and a second emitter, wherein the light emitted by the first emitters in operation is directed by the optical element in a different direction than the light emitted by the second emitters in operation.

7. The optoelectronic module according to claim 6, wherein the first emitters and the second emitters each lie on a common connecting axis.

8. The optoelectronic module according to claim 1, which has a control unit for separate control of the emission regions.

9. The optoelectronic module according to claim 1, wherein the emitters of each emission region are monolithically formed with each another.

10. The optoelectronic module according to claim 1, wherein the emitters of each emission region are arranged separately on the carrier.

11-12. (canceled)

13. The optoelectronic module according to claim 1, wherein the carrier has at least one of the following structures:
integrated circuit,
complementary metal-oxide-semiconductor structure,
application-specific integrated circuit.

14. (canceled)

15. A display element comprising a plurality of optoelectronic modules according to claim 1, wherein
the optoelectronic modules are arranged side by side in the lateral direction (x) at the nodes of a regular 2-dimensional lattice on a display element carrier, the lateral direction (x) being parallel to the main plane of extension of the carrier, and
each of the emission regions has a first emitter and a second emitter, whereby the light emitted by the first emitters in operation exits the display element at a different exit angle than the light emitted by the second emitters.

16. The display element according to claim 15, wherein at least one optical element is arranged downstream of the optoelectronic modules in a radiation direction.

17. The display element according to claim 15, wherein in operation different perspectives of an image can be displayed, whereby the simultaneous perception of different perspectives produces a three-dimensional image impression.

18. An optoelectronic module with:
a carrier with a main plane of extension,
a first emission region with a plurality of emitters of a first type, which are configured to emit light of at least one predeterminable first color location during operation of the optoelectronic module,
a second emission region with a plurality of emitters of a second type, which are configured to emit light of at least one predeterminable second color location during operation of the optoelectronic module, and
a third emission region with a plurality of emitters of a third type, which are configured to emit light of at least one predeterminable third color location during operation of the optoelectronic module, wherein
the emission regions are arranged spaced apart from each other on the carrier, and
an optical element is arranged downstream of each of the emission regions in an emission direction.

19. The optoelectronic module according to claim 18, wherein the emitters of each emission region are arranged along an at least 1-dimensional lattice.
